(19) United States
(12) Patent Application Publication
(10) Pub. No.: US 2016/0005574 A1
(43) Pub. Date: Jan. 7, 2016

(54) PEVCD DEVICE AND METHOD USING PECVD TECHNOLOGY ON SUBSTRATE

(71) Applicant: SHEZHEN CHINA STAR OPTOELECTRONICS TECHNOLOGY CO., LTD., Shenzhen (CN)

(72) Inventor: Fengju LIU, Shenzhen (CN)

(21) Appl. No.: 14/345,954

(22) PCT Filed: Jan. 23, 2014
(86) PCT No.: PCT/CN2014/071174

§ 371 Date: Mar. 20, 2014

(51) Int. Cl. H01J 37/32; C23C 16/509

(52) U.S. Cl. CPC H01J 37/32568; H01J 37/32091; C23C 16/509; H01J 2237/3321; H01J 2237/3323; H01J 2237/327

(57) ABSTRACT

A plasma enhanced chemical vapor deposition (PECVD) device includes a deposition box, a first electrode, and a second electrode, where the first electrode and the second electrode are arranged in the deposition box. A process chamber is arranged in the deposition box, a gas line and a pump port are respectively arranged along a first side wall and a second side wall of the deposition box, and a valve is arranged along a third side wall of the deposition box. The first electrode is arranged in an inside of the process chamber, and is connected to a radio frequency (RF) power source. A first end of the first electrode corresponds to the valve and is adjacent to the pump port. The PECVD device further includes an electrode regulating device, the electrode regulating device adjusts an angle between the first electrode and the second electrode to make a plasma airflow between the first electrode and the second electrode be even, which reduces a thickness difference of a film in different areas due to the airflow deflecting to a valve.

### TECHNICAL FIELD

The present disclosure relates to manufacture of liquid crystal display devices, and more particularly to a plasma enhanced chemical vapor deposition (PECVD) device and a method using PECVD technology on a substrate.

### BACKGROUND

When a SiNx film and an ASi film of a thin film transistor liquid crystal display (TFT-LCD) are generated on a glass substrate through a plasma enhanced chemical vapor deposition (PECVD) process chamber, thickness of the film on different areas of the glass substrate is slightly different. If difference of the thickness is great, electrical property differences of a TFT device becomes great, which causes performance differences between different areas of a TFT-LCD device. For example, color difference is generated in different areas of the TFT-LCD device, thus, quality of the TFT-LCD device reduces. It should be understood that when the film made of other materials is generated through the PECVD process Chamber, the thickness of the film is also different in different areas of the glass substrate, which also reduces the quality of a display device.

As shown in FIG. 1, a typical PECVD device includes a pump port 160 and a valve 150, the pump port 160 and the valve 150 are arranged along a same side of the typical PECVD device, which causes airflow to deflect to the valve 150. Additionally, an open area 151 is arranged along a front of the valve 150, and the open area 151 also causes plasma to deflect to the valve 150. Thus, the thickness of the film generated on the glass substrate 180 that is close to the valve is great. At present, distribution of the plasma between electrode plates is changed through adjusting, position of a radio frequency (RF) power source relative to a first electrode 140, which changes uniformity of the thickness of the film generated in different areas. However, temperature of the display device needs be reduced in the above-mentioned method, and a chamber lid of the PECVD device needs be disassembled, which wastes time and energy. And, the site of the RF power source relative to the first electrode 140 needs be adjusted many times to obtain an even thickness of the film, which reduces useful efficiency of the device.

### SUMMARY

The aim of the present disclosure is to provide a plasma enhanced chemical vapor deposition (PECVD) device and a method applying PECVD technology on a substrate capable of high efficiency and forming even film.

The aim of the present disclosure is achieved by the following methods.

A plasma enhanced chemical vapor deposition (PECVD) device comprises a deposition box, a first electrode connecting to a power source, a second electrode being opposite to the first electrode, and an electrode regulating device. A process chamber is arranged in the deposition box, a gas line and a pump port which are respectively arranged along a first side wall and a second side wall of the deposition box, and a valve is arranged along, a third side wall of the deposition box. The pump port is arranged along a side of the second side wall adjacent to the third side wall. A first end of the first electrode corresponds to the valve and is adjacent to the pump port. The electrode regulating device adjusts an angle between the first electrode and the second electrode to make a plasma airflow between the first electrode and the second electrode be even.

Furthermore, the electrode regulating device comprises a supporting bar and a regulation member that adjusts an angle of the supporting bar, where the supporting bar directly supports the second electrode. The second electrode is not directly connected to a line of the power source, thus, the second electrode that simplifies a structure of the regulation member is adjusted.

Furthermore, the regulation member comprises a regulating bar fixed to the supporting bar. Two ends of the regulating bar are respectively configured with a first screw and a second screw, and the first screw and the second screw are configured with a nut fastening the screws. The first screw and the second screw are in top pressure with a wall surface of the deposition box. An angle of the regulating bar is adjusted through adjusting the first screw and the second screw, and an angle of the supporting bar is adjusted. The structure of the supporting bar is directly adjusted through the first screw and the second screw is simple, is easy to adjust the angle of supporting bar, and has high precision of regulation.

Furthermore, the electrode regulating device comprises a first screw and a second screw that are respectively arranged along two ends of the second electrode and directly support the second electrode, the first screw and the second screw are configured with a nut fastening the screws. This is another example, the electrode regulating device is directly supported by the two screws, the angle of the electrode regulating device can be adjusted, and the regulation precision is great.

Furthermore, the electrode regulating device is configured with a scale. The quantitative regulation is obtained through the scale, which can perform corresponding angle regulation according to different thickness requirements of the film.

A method using plasma enhanced chemical vapor deposition (PECVD) technology on a substrate comprises:

S: adjusting an angle between a first electrode and a second electrode in a deposition box, and making a plasma airflow between the first electrode and the second electrode be even.

Furthermore, the angle between the first electrode and the second electrode is adjusted through adjusting an angle of the second electrode, and an adjustment of the angle of the second electrode is obtained through an electrode regulating device arranged along the second electrode.

Furthermore, the electrode regulating device comprises a supporting bar and a regulation member that adjusts an angle of the supporting bar, where the supporting bar directly supports the second electrode.

Furthermore, the regulation member comprises a regulating bar fixed to the supporting bar. Two ends of the regulating bar are respectively configured with a first screw and a second screw, and the first screw and the second screw are configured with a nut fastening the screws. The first screw and the second screw are in top pressure with a wall surface of the deposition box. An angle of the regulating bar is adjusted through adjusting the first screw and the second screw, and an angle of the supporting bar is adjusted.

Furthermore, the electrode regulating device comprises a first screw and a second screw that are respectively arranged along two ends of the second electrode and directly support the second electrode, the first screw and the second screw are configured with a nut fastening the screws.

In the present disclosure, the PECVD device is configured with the electrode regulating device, the electrode regulating device is used for adjusting the angle between the first electrode and the second electrode to make the plasma airflow between the two electrodes be even, thus, the thickness of the film generated on the glass substrate is even, which reduces the thickness difference of the film in different areas of the glass substrate due to the airflow deflecting to the valve of the PECVD device.

### BRIEF DESCRIPTION OF FIGURES

FIG. 1 is a structural diagram of a typical plasma enhanced chemical vapor deposition (PECVD) device.

FIG. 2 is a structural diagram of the PECVD device of a first example of the present disclosure.

FIG. 3 is a schematic diagram of the PECVD device of the first example of the present disclosure.

FIG. 4 is a structural diagram of the PECVD device of the second example of the present disclosure.

FIG. 5 is a flowchart of a method for generating a film through using PECVD technology of the present disclosure.

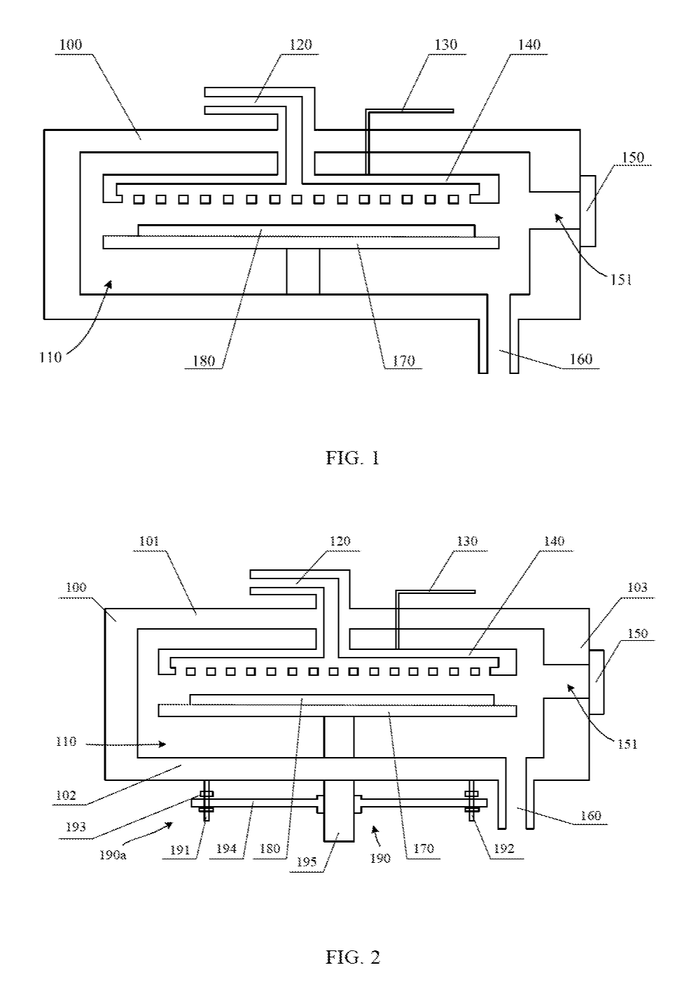

### DETAILED DESCRIPTION

The present disclosure will further be described in detail in accordance with the figures and the exemplary examples.

### Example 1

As shown in FIGS. 2-3, an improved PECVD device comprises a deposition box 100, a first electrode 140, and a second electrode 170, where the first electrode 140 and the second electrode 170 are arranged in the deposition box 100. A process chamber 110 is arranged along an inside of the deposition box 100, a gas line 120 and a pump port 160 are arranged along a first side wall 101 and a second side wall 102 of the deposition box 100, respectively, and a valve 150 is arranged along a third side wall 103 of the deposition box 100. The pump port 160 is arranged along a side of the second side wall 102 that is adjacent to the third side wall 103, which allows plasma to flow freely in the process chamber 110. The first electrode 140 arranged along the inside of the process chamber 110 is connected to a radio frequency (RF) power source 130, a first end of the first electrode 140 corresponds to the valve 150 and is adjacent to the pump port 160. An open area 151 is arranged along a front of the valve 150, and the second electrode 170 is opposite to the first electrode 140. When a film is needed to form (e.g. a SiNx film and an ASi film), a glass substrate 180 is disposed on the second electrode 170, the plasma is pumped into the process chamber and processed through the PECVD. The second electrode 170 is configured with an electrode regulating device 190, the electrode regulating device 190 adjusts an angle between the first electrode 140 and the second electrode 170 to make a plasma airflow between first electrode 140 and the second electrode 170 be even, which reduces thickness difference of the film in different areas of the glass substrate, where the thickness difference is caused by the airflow deflecting to the valve 150. As shown in FIG. 3, the airflow deflects a determined angle because an angle of the second electrode 170 is changed, which improves the uniformity of the thickness of the film.

The electrode regulating device 190 comprises a supporting bar 195 and a regulation member 190a that adjusts an angle of the supporting bar 195, where the supporting bar 195 directly supports the second electrode 170. In the first example, the second electrode 170 is not directly connected to a line of the power source, and the electrode regulating device 190 is arranged along the second electrode, which simplifies a structure of the regulation member 190a. It should be understood that the electrode regulating device 190 also may be arranged along the first electrode 140 to control the plasma airflow.

In the first example, the regulation member 190a comprises a regulating bar 194 that is fixed to the supporting bar 195. Two ends of the regulating bar 194 are respectively configured with a first screw 191 and a second screw 192, and the first screw 191 and the second screw 192 are configured with a nut 193 that fastening the screws. The first screw 191 and the second screw 192 are in top pressure with a wall surface of the deposition box 100. An angle of the regulating bar 194 is adjusted through adjusting the first screw 191 and the second screw 192, which adjusts an angle of the supporting bar 195, and an angle of the second electrode 170 is accordingly changed. The structure of the supporting bar 195 is directly adjusted through the first screw 191 and the second screw 192 is simple, and is easy to adjust the angle of supporting bar 195, and has high precision of regulation.

In order to obtain higher precision of regulation and adjust the thickness of the film for different requirements, the electrode regulating device 190 is configured with a scale, a quantitative regulation is obtained, which is more accurate and convenient.

### Example 2

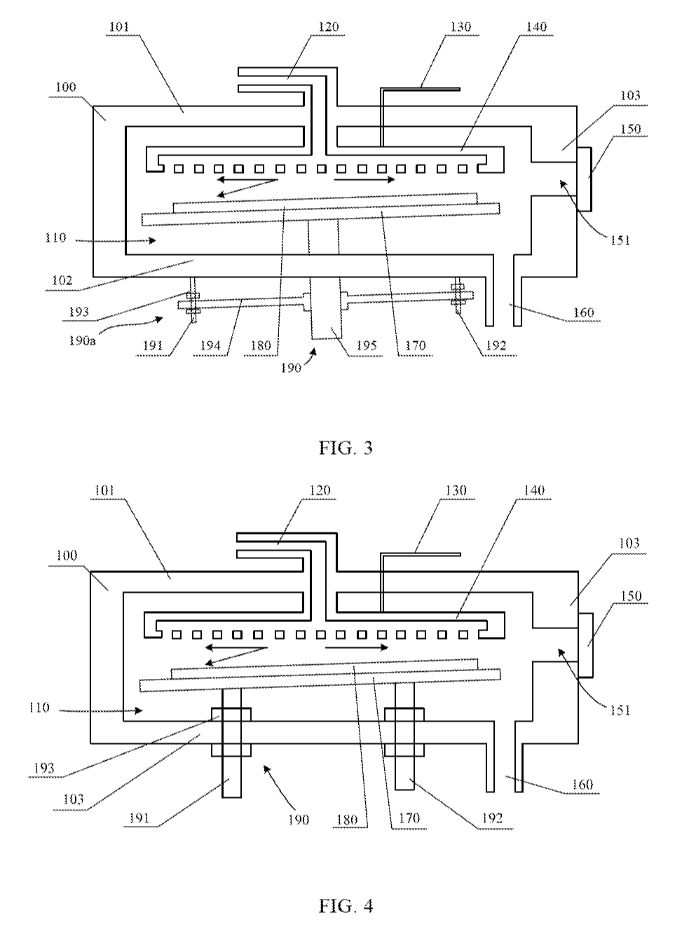

A second example is shown in FIG. 4, and the structure of the electrode regulating device 190 of the second example is different from the first example. The electrode regulating device 190 of the second example comprises the first screw 191, the second screw 192, and the nut 193 fastening the first screw 191 and the second screw 192, where the first screw 191 and the second screw 192 are respectively arranged along two ends of the second electrode 170 and directly support the second electrode 170. The electrode regulating device 190 of the second example is directly supported by the two screws, the angle of the electrode regulating device 190 can be adjusted, and the regulation precision is great.

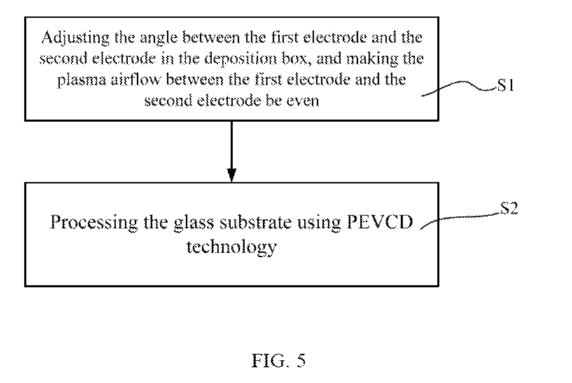

As shown in FIG. 5, The present disclosure provides a method using the PECVD technology on the substrate, the method comprises:

S1: adjusting the angle between the first electrode and the second electrode in the deposition box, and making the plasma airflow between the first electrode and the second electrode be even; and
S2: Processing the glass substrate using the PECVD technology.

In the method, the angle between the first electrode and the second electrode is adjusted through adjusting the angle of the second electrode, and the electrode regulating device arranged along the second electrode adjusts the angle of the second electrode (170). The device of the first example or the second example is used in the method.

The present disclosure is described in detail in accordance with the above contents with the specific exemplary examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

We claim:

1. A plasma enhanced chemical vapor deposition (PECVD) device, comprising:
a deposition box (100);
a first electrode (140) connecting to a power source (130);
a second electrode (170) opposite to the first electrode (140); and
an electrode regulating device;
wherein a process chamber (110) is arranged in the deposition box (100), a gas line (120) and a pump port (160) are arranged along a first side wall (101) and a second side wall (102) of the deposition box (100), respectfully, and a valve (150) is arranged along a third side wall (103) of the deposition box (100); the pump port (160) is arranged along a side of the second side wall (102) adjacent to the third side wall (103); a first end of the first electrode (140) corresponds to the valve (150) and is adjacent to the pump port (160); the electrode regulating device (190) adjusts an angle between the first electrode (140) and the second electrode (170) to make a plasma airflow between the first electrode (140) and the second electrode (170) be even.

2. The PECVD device of claim 1, wherein the electrode regulating device (190) comprises a supporting bar (195) and a regulation member (190a), the supporting bar (195) directly supports the second electrode (170), and the regulation member (190a) adjusts an angle of the supporting bar (195).

3. The PECVD device of claim 2, wherein the regulation member (190a) comprises a regulating bar (194) fixed to the supporting bar (195); two ends of the regulating bar (194) are respectively configured with a first screw (191) and a second screw (192), and the first screw (191) and the second screw (192) are configured with a nut (193) fastening the screws (191/192); the first screw (191) and the second screw (192) are in top pressure with a wall surface of the deposition box (100); an angle of the regulating bar (194) is adjusted through adjusting the first screw (191) and the second screw (192), and an angle of the supporting bar (195) is adjusted.

4. The PECVD device of claim 1, wherein the electrode regulating device (190) comprises a first screw (191) and a second screw (192) that are respectively arranged along two ends of the second electrode (170) and directly support the second electrode (170); the first screw (191) and the second screw (192) are configured with a nut (193) fastening the first screws (191/192).

5. The PECVD device of claim 3, wherein the electrode regulating device is configured with a scale.

6. A method using plasma enhanced chemical vapor deposition (PECVD) technology on a substrate, comprising:
S: adjusting an angle between a first electrode (140) and a second electrode (170) in a deposition box (100) to make a plasma airflow between the first electrode (140) and the second electrode (170) be even.

7. The method using the PECVD technology on the substrate of claim 6, wherein the angle between the first electrode (140) and the second electrode (170) is adjusted through adjusting an angle of the second electrode (170), and an electrode regulating device (190) arranged along the second electrode (170) adjusts the angle of the second electrode (170).

8. The method using the PECVD technology on the substrate of claim 7, wherein the electrode regulating device (190) comprises a supporting bar (195) and a regulation member (190a), the supporting bar 195 directly supports the second electrode (170), and the regulation member (190a) adjusts an angle of the supporting bar (195).

9. The method using the PECVD technology on the substrate of claim 8, wherein the regulation member (190a) comprises a regulating bar (194) fixed to the supporting bar (195); two ends of the regulating bar (194) are respectively configured with a first screw (191) and a second screw (192), and the first screw (191) and the second screw (192) are configured with a nut (193) fastening the screws (191/192); the first screw (191) and the second screw (192) are in top pressure with a wall surface of a deposition box (100); an angle of the regulating bar (194) is adjusted through adjusting the first screw (191) and the second screw (192), and an angle of the supporting bar (195) is adjusted.

10. The method using the PECVD technology on the substrate of claim 7, wherein the electrode regulating device (190) comprises a first screw (191) and a second screw (192) that are respectively arranged along two ends of the second electrode (170) and directly support the second electrode (170); the first screw (191) and the second screw (192) are configured with a nut (193) fastening the screws (191/192).
